(19) United States
(12) Patent Application Publication
(10) Pub. No.: US 2015/0084680 A1
(43) Pub. Date: Mar. 26, 2015

(54) STATE RETENTION POWER GATED CELL FOR INTEGRATED CIRCUIT

(71) Applicants: Zhihong Cheng, Suzhou (CN); Zhijun Chen, Suzhou (CN); Huabin Du, Suzhou (CN); Peidong Wang, Suzhou (CN); Shayan Zhang, Cedar Park, TX (US)

(72) Inventors: Zhihong Cheng, Suzhou (CN); Zhijun Chen, Suzhou (CN); Huabin Du, Suzhou (CN); Peidong Wang, Suzhou (CN); Shayan Zhang, Cedar Park, TX (US)

(21) Appl. No.: 14/191,403

(22) Filed: Feb. 26, 2014

(30) Foreign Application Priority Data
Sep. 25, 2013 (CN) 201310680309.5

(51) Int. Cl. H03K 17/22

(52) U.S. Cl. CPC H03K 17/22
USPC 327/198

(57) ABSTRACT

A state retention power gated (SRPG) cell includes a retention circuit coupled to a power gated circuit. The retention circuit stores state information of the power gated circuit before a low power period is started. A gated power supply coupled to the power gated circuit and to a first end of a power supply switch supplies a gated supply voltage to the power gated circuit during a non-low power period. A local power supply coupled to the retention circuit and to a second end of the power supply switch is coupled to the gated power supply in the non-low power period, and a non-gated power supply is coupled to the local power supply via an isolation element to isolate the non-gated power supply from the local power supply during the non-low power period, and to couple the non-gated power supply to the local power supply during the low power period.

### BACKGROUND OF THE INVENTION

The present invention relates to digital integrated circuits, and, more particularly, to a state retention power gated cell for an integrated circuit.

Power gated circuits have been developed as a technique for reducing the power consumption of integrated circuits. During periods when one or more portions, or modules, of the integrated circuit are not required to operate, the power supplies to these modules can be shut down thereby reducing the power dissipated due to leakage in those modules. When the module is required to operate, a power on process is performed whereby the power supply to that module is restored and operation resumed.

Some functions of an integrated circuit will require state data to be maintained throughout a low power period (when the power supply is shut down). State retention power gating (SRPG) has been introduced as a way of saving state data during the low power period. To use this technique retention circuits are provided to store the state information of a power gated circuit when the power to that circuit has been gated off. Upon restoration of the power supply to the power gated circuit, the integrated circuit can quickly recover to the state it was in before it was powered down and continue operation on that state.

In order to store the state information in the retention circuits during the low power periods, the retention circuits are provided with a non-gated power supply. The retention circuits are typically designed to have very low power consumption and therefore may be supplied via a weak power grid that must be provided alongside the normal gated power supply for that portion of the integrated circuit. Additional power grids can make placement and routing difficult and also can cause timing issues is cells are placed far apart. It would be advantageous to have an SRPG cell that was easier to place and route and fit into an integrated circuit design.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 is a top plan view of a layout of a portion of an integrated circuit including conventional state retention power gated (SRPG) cells;

FIG. 2 is a schematic block diagram of a SRPG cell in accordance with an embodiment of the present invention;

FIG. 3 is a top plan view of a partial layout of an integrated circuit including the SRPG cell of FIG. 2;

FIG. 4 is a schematic circuit diagram of an SPRG cell in accordance with an embodiment of the present invention;

FIG. 5 is a schematic circuit diagram of another SRPG cell in accordance with an embodiment of the present invention;

FIG. 6 is a schematic circuit diagram of an isolation cell in accordance with an embodiment of the present invention; and

FIG. 7 shows a graph of voltage levels in the SRPG cell of FIG. 2 during entry to and exit from a low power state.

### DETAILED DESCRIPTION OF THE PREFERRED EMBODIMENTS

The illustrated embodiments of the present invention may for the most part, be implemented using electronic components and circuits known to those skilled in the art. Therefore, details will not be explained in any greater extent than that considered necessary for the understanding and appreciation of the underlying concepts of the present invention and in order not to obfuscate or distract from the teachings of the present invention.

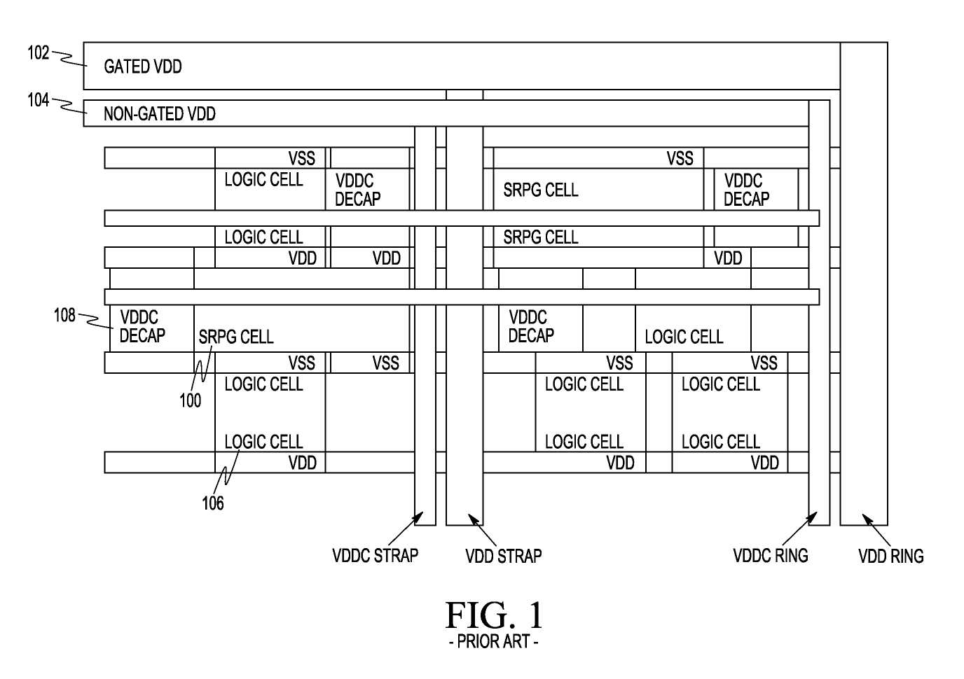

FIG. 1 illustrates a layout of a portion of an integrated circuit including conventional state retention power gated (SRPG) cells 100 and a number of further logic cells 106. Gated VDD 102 provides the main power supply while non-gated VDDC 104 provides supplementary power supply to part of the SRPG cells 100 during operation of the circuits, but is gated off during low power periods. Power is provided to the SRPG cells 100 during low power periods only via the non-gated VDDC 104.

The presence of the separate non-gated VDDC 104 mesh impacts on the design of integrated circuits by occupying a significant area of silicon in the design, and requiring the inclusion of VDDC decap cells 108 to decouple the high frequency switching noise or IR drop during operation of the integrated circuit associated with the non-gated VDDC 104. Thus, this arrangement requires significant extra silicon area, resulting in low silicon utilization in the design. Furthermore, the larger area of silicon requires longer signal wires for routing signals between cells, which may introduce difficulties due to increased signal noise and timing issues in signal propagation.

According to some embodiments of the present invention, the non-gated VDDC power mesh may be eliminated without impacting the function or performance of an integrated circuit including SRPG cells.

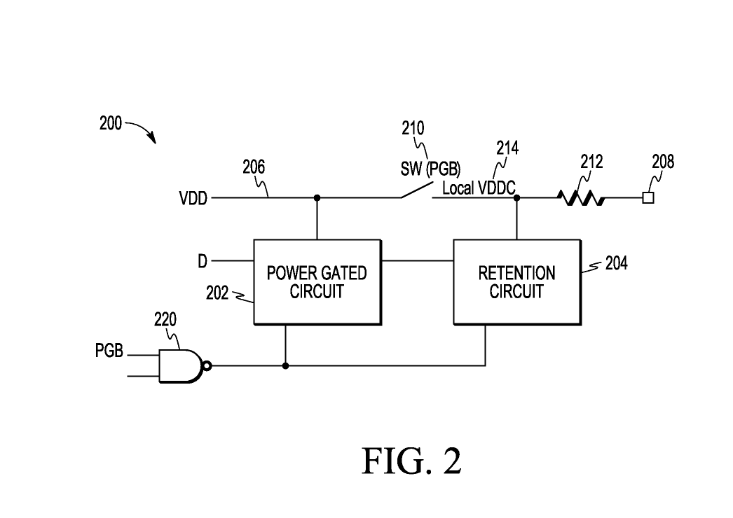

Referring now to FIG. 2, a schematic block diagram of an SRPG cell 200 according to an embodiment of the present invention is shown. The SRPG cell 200 comprises a power gated circuit 202 coupled to a retention circuit 204 to allow state data to be stored in the retention circuit 204 during low power periods. A gated power supply (VDD) 206 is coupled to the power gated circuit 202 and also to a switch 210. The retention circuit 204 is coupled to a local power supply (VDDC_loc) 214. The local power supply 214 is coupled to the switch 210 such that during normal operation of the cell 200 the switch 210 is controlled by a switch control signal 220 to electrically couple the local power supply 214 to the gated power supply VDD 206, and during low power periods, the switch 210 is opened to isolate the local power supply (VDDC_loc) 214 from the gated power supply VDD 206. The local power supply 214 is further coupled to a non-gated VDDC power net by way of an isolation circuit 212 and a VDDC pin 208.

During normal operation or functional mode of the circuit, the switch 210 is closed, electrically coupling the gated power supply 206 to the local power supply 214 such that the gated power supply 206 provides current to both the power gated circuit 202 and the retention circuit 204. While the gated supply 206 is coupled to the local power supply 214, the isolation circuit 212 operates to limit current flowing into the local power supply 214 from the non-gated VDDC net, such that substantially no current flows from the non-gated VDDC net during functional mode.

During low power periods, the switch 210 is opened and isolates the local power supply 214 from the gated supply 206. The isolation circuit 212 operates to conduct a limited current from the VDDC net to supply the retention circuit 204 while maintaining state data during the low power period.

In the SRPG cell 200, substantially all of the current used by both the power gated circuit 202 and the retention circuit 204 during functional mode is provided by the gated power supply 206. The relatively larger current required during switching of the components within the retention circuit 204 is therefore supplied by the gated supply 206.

During low power mode, generally the only current that is required by the retention circuit 204 is the leakage current associated with the components of the retention circuit 204. Typically, this leakage current is significantly smaller than the dynamic switching current during operation of the circuit. Thus, the current that must be supplied from the VDDC net during low power mode is relatively small for example on the order of pico-amperes.

According to some embodiments, the electrical connection between the SRPG cell 200 and the VDDC net may comprise a normal signal wire capable of conducting sufficient current to meet the leakage current demands of the retention circuit 204.

According to some embodiments, the isolation circuit 212 may comprise a diode, for example a PMOS transistor with its gate and drain electrically coupled to operate as a diode. In some other embodiments a controlled switch device could be used.

In one embodiment, a preferred overall metal lines routing resource ratio between the VDD mesh (power gated supply) and the VDDC (non-gated power supply for retention) is about 3:1 in average. In a typical SoC power rail design, a conventional VDDC power strap is no longer needed, and the VDDC power delivery routes can be implemented essentially using minimum metal width lines. The saved routing tracks/resources from VDDC can be reallocated to the VDD power mesh in order to reduce dynamic I*R drop and improve Electro-Migration reliability.

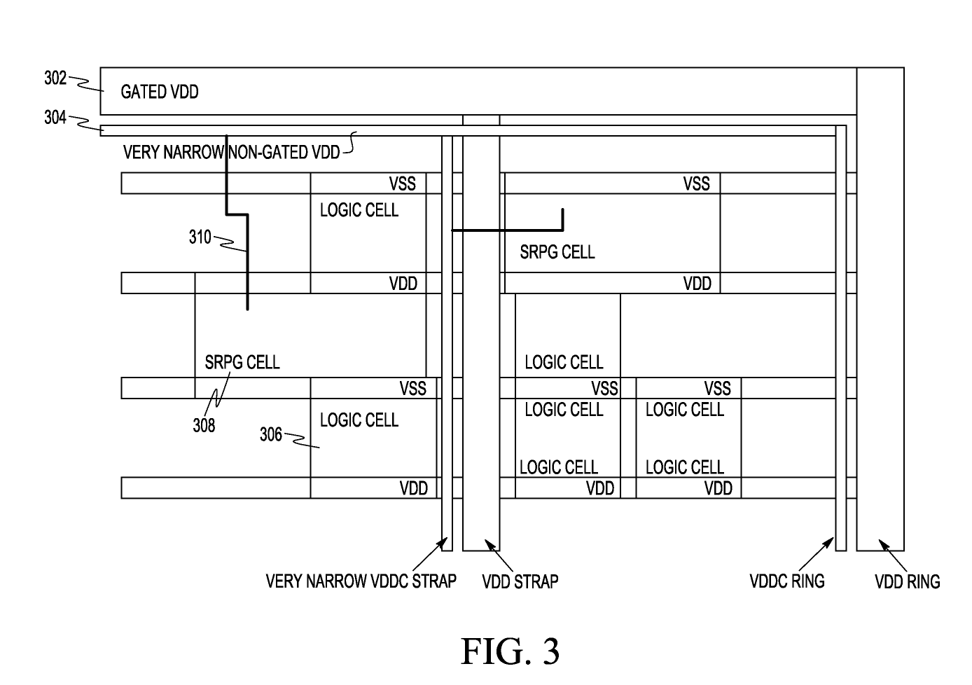

FIG. 3 provides a schematic illustration of a silicon layout for a portion of an integrated circuit including the SRPG cell 200 of FIG. 2 (here labelled as 308). In the integrated circuit of FIG. 3, the size (i.e. width) of the conductors in the VDDC net 304 is reduced, reducing the area of silicon required, as the current that must be supplied by the VDDC net is reduced for the SPRG cells 308. Furthermore, the use of signal lines 310 to connect the SRPG cells 308 to the VDDC net 304 allows the VDDC decap cells 108 of FIG. 1 to be eliminated, further reducing the silicon area for the design. This allows a more compact design to be realised for the circuit functionality having shorter signal interconnections, and therefore lower noise and fewer timing issues.

According to some embodiments of the invention the retention circuit is configured to further reduce the leakage current through the retention circuit that must be supplied from the VDDC net during low power mode.

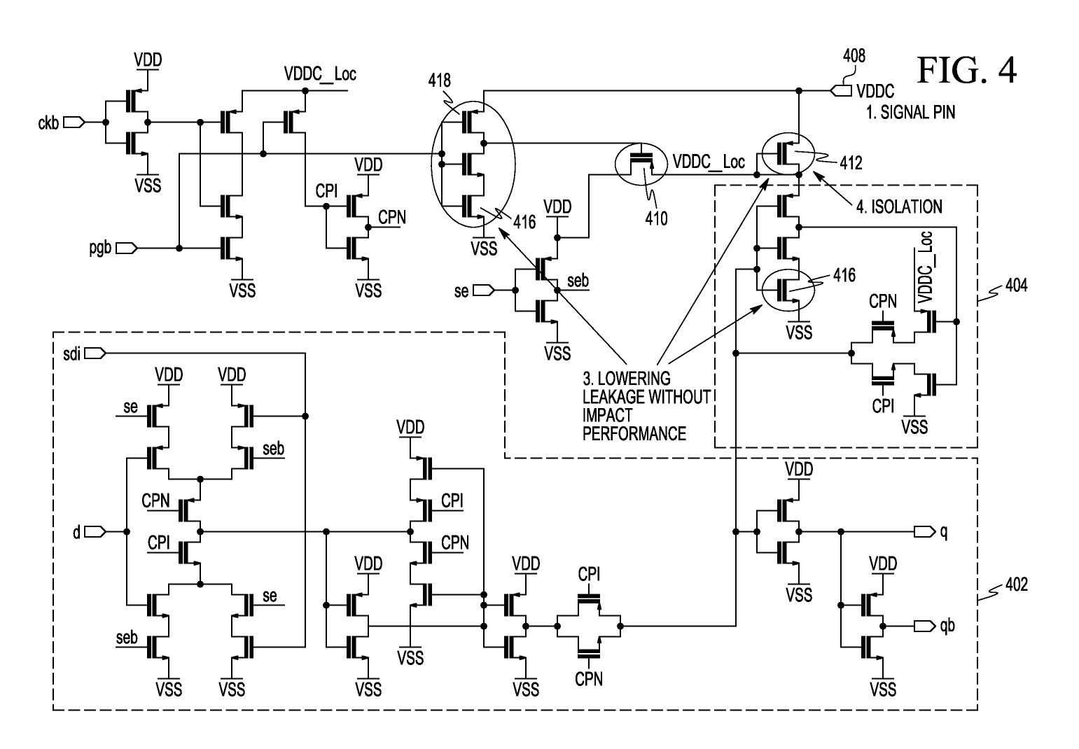

FIG. 4 is a schematic circuit diagram of an SRPG cell according to an embodiment of the present invention. In FIG. 4, the portion of the circuit indicated by box 402 substantially corresponds to the power gated circuit 202 of FIG. 2. Similarly, circuit elements 404 substantially correspond to the retention circuit 204; elements 410 to the switch 210; and transistor 412 to the isolation element 212. The local power supply 414 is coupled to VDD through switch 410 in functional mode, and to the VDDC net via signal pin 408 in low power mode. NMOS transistors 416 are provided to further reduce the leakage current through the switch 410 and in retention circuit 404 when in low power mode.

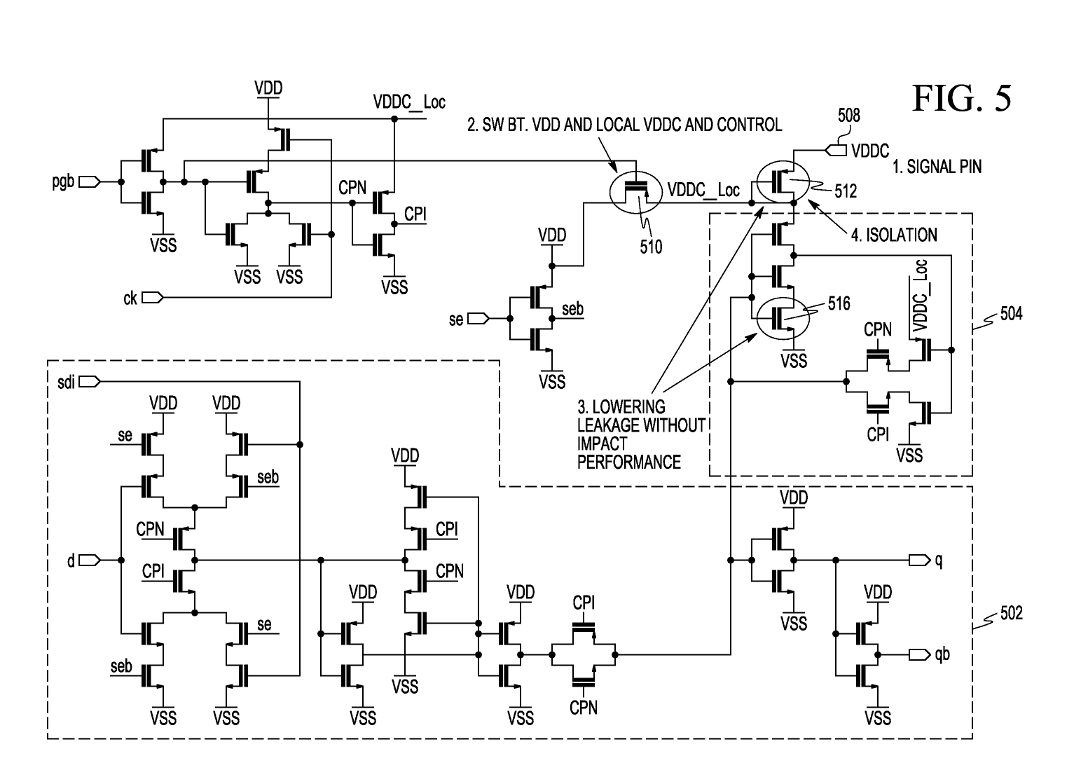

FIG. 5 shows a circuit diagram for a further SRPG cell according to an embodiment of the present invention. The embodiment of FIG. 5 is similar to that shown in FIG. 4, with element 502 corresponding to 402; 504 to 404; 508 to 408; and 510 to 410. As can be seen in FIG. 5, PMOS transistor 512 acts as an isolation element between the VDDC signal pin 508 and the retention circuit 504. The retention circuit 504 further includes NMOS transistor 516 to help reduce leakage current through the retention circuit 504.

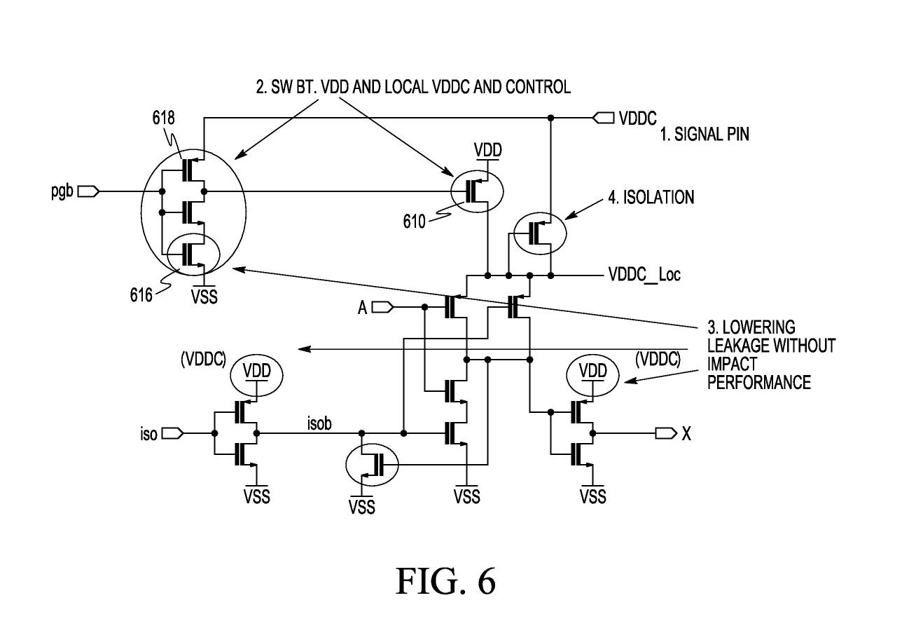

FIG. 6 shows a circuit diagram of an isolation cell in accordance with an embodiment of the present invention. The isolation cell provides isolation between a first portion of logic that is powered-down in a low power period and a second portion of logic that remains powered and in a functional state during the low power period. The isolation cell ensures that a defined logic level is present on an output of the first portion of logic during the low power period. In the isolation cell of FIG. 6, a similar arrangement is used as with the SRPG cells of FIGS. 4 and 5 to provide isolation between the switched power supply and the non-switched power supply used during retention mode. In particular, a switch 610 is operable to couple the gated power supply to a local power supply 614, while an isolation circuit 612 is operable to limit current flowing into the local supply 614 from the non-gated VDDC net during a non-low power period, i.e. when the circuit is in functional mode.

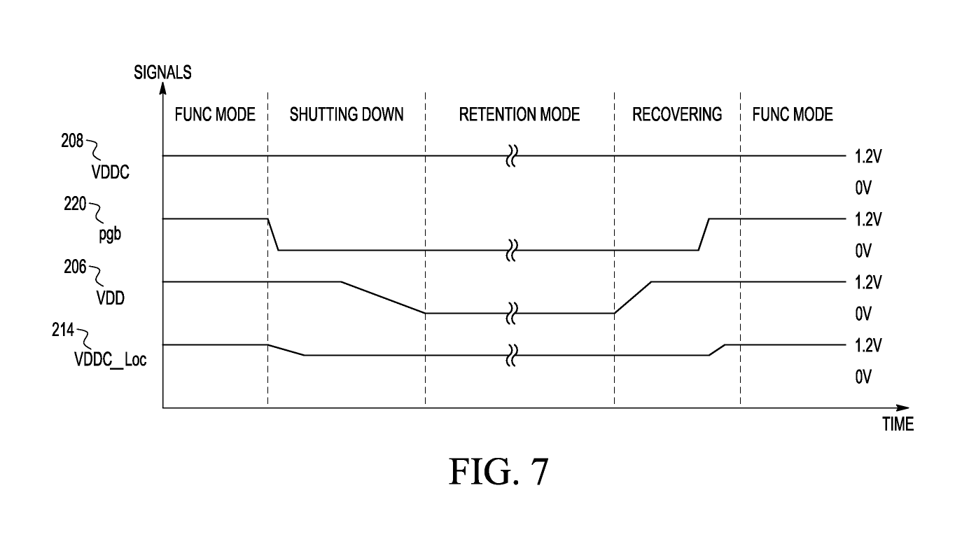

FIG. 7 shows a graph of voltage levels in a SRPG cell through different modes of operation according to embodiments of the invention. During a first period, the SRPG cell in in functional mode and the control signal (pgb) 220 to switch 210 is high resulting in the gated power supply (VDD) 206 being coupled to the local power supply (VDDC_loc) 214. During this period VDD and VDDC_loc are electrically coupled and are therefore at the same voltage level, and the retention circuit 204 receives current from the gated power supply 206 by way of the local power supply 214.

When the integrated circuit is to enter a low power mode, the SRPG cell enters a shutdown period in which the level switch control signal 220 is negated, opening the switch 210 and isolating the local power supply 214 from the gated supply 206. Due to the presence of leakage currents through the retention circuit, the VDDC_loc voltage level begins to drop until isolation circuit 212 begins to conduct. Current then flows from the VDDC net through the isolation element 212 to the local power supply 214, and the voltage of the local power supply 214 is maintained. The gated supply 206 is then gated off and drops to zero and retention, or low power mode, is entered.

Retention mode can then be maintained for as long as appropriate, until the integrated circuit is desired to function again. To wake up the SRPG cell, first the gated power supply 206 is gated on, and recovers to its normal operating voltage. Then the switch control signal 220 is asserted coupling the local power supply 214 to the gated supply 206. This causes the voltage of the local power supply to rise to match the voltage of the gated supply 206. As the voltage of the local power supply 214 increases, isolation element 212 will cease to conduct and again isolate the local power supply from the VDDC net. The SRPG cell can then function as normal, with electrical current supplied to the retention circuit 204 during operation from the gated supply 206.

As described above, embodiments of the invention may allow current to be supplied to a SRPG cell in low power mode via a thin signal wire, rather than requiring a large VDDC mesh. Such signal wires require negligible surface area and therefore allow the size of routing VDDC to be reduced. Further techniques can be applied to the SRPG cell to reduce leakage current that must be supplied during low power mode, without impacting performance of the circuit in function mode.

During functional mode, any noise coupled to the VDDC net is isolated from the SRPG circuit by the isolation element, and therefore embodiments of the invention may have very good noise resistance. During low power mode, less noise will be experienced due to the gating off of the power supply to most of the integrated circuit, and therefore is not of concern.

In the foregoing specification, the invention has been described with reference to specific examples of embodiments of the invention. It will, however, be evident that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with single connections that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will be appreciated that conductivity types and polarities of potentials may be reversed. Similarly, the signals described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “de-assert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality without departure from the spirit of this invention.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. An integrated circuit, comprising:
a power gated circuit (202) that is shut down during a low power period;
a retention circuit (204) coupled to the power gated circuit (202) during at least a portion of the non-low power period, wherein the retention circuit (204) stores, during the low power period, state information reflecting a state of the power gated circuit (202) before the low power period started;
a gated power supply (206) coupled to the power gated circuit (202) and to a first end of a power supply switch (210) for supplying a gated supply voltage to the power gated circuit (202) during a non-low power period;
a local power supply (214) coupled to the retention circuit (204) and to a second end of the power supply switch (210), wherein during the non-low power period the local power supply (214) is coupled to the gated power supply (206) via the switch (210); and
a non-gated power supply (208) coupled to the local power supply (214) via an isolation element (212);
wherein the isolation element (212) isolates the non-gated power supply (208) from the local power supply (214) during the non-low power period, and couples the non-gated power supply (208) to the local power supply (214) during the low power period.

2. The integrated circuit of claim 1, wherein the isolation element (212) comprises one of a diode and a PMOS transistor (412) having a source terminal coupled to the non-gated power supply (408), and drain and gate terminals coupled to the local power supply (414).

3. The integrated circuit of claim 1, wherein the isolation element (212) is configured to reduce the leakage current of the retention circuit (204) during the low power period and to isolate a noise signal from coupling with the retention circuit (204) from the non-gated power supply (208).

4. The integrated circuit of claim 1, wherein the non-gated power supply (208) comprises a signal wire (310) coupled between a non-gated power supply net (304) and the isolation element (212).

5. The integrated circuit of claim 4, wherein the signal wire (310) electrically couples the isolation element (212) to the non-gated power supply net (304).

6. The integrated circuit of claim 4, where the signal wire (310) is configured to limit a stray capacitance associated with the non-gated power supply (208).

7. The integrated circuit of claim 1, wherein the retention circuit (204) further comprises one or more transistors (416) configured to reduce leakage current during the low power period.

8. A method for recovering from a low power period, the method comprising:
supplying a gated supply voltage (206) to a power gated circuit (202) and to a first end of a switch (210) during a non-low power period before the low power period;
supplying a local power supply voltage (214) to a retention circuit (204) coupled to the power gated circuit, the local power supply voltage (214) coupled to a second end of the switch (210), wherein the switch (210) is closed during the non-low power period and open during the low power period, and the local power supply voltage (214) is coupled to a non-gated power supply (208) via an isolation element (212) during the low power period;
saving, at the retention circuit (204), during the low power period, state information reflecting the state of the power gated circuit (202) before the low power period started; and
recovering from the low power period by closing the switch (210) and providing the gated supply voltage to the power gated circuit (202);
wherein recovering from the low power period further comprises isolating, at the isolation element (212), the non-gated power supply (208) from the local power supply (214).

9. The method of claim 8, further comprising asserting a signal (220) to indicate that the power gated circuit (202) and the retention circuit (204) have entered a functional operation mode during a non-low power period.

10. The method of claim 8, wherein the isolation element comprises one of a diode and a PMOS transistor (412) having a source terminal coupled to the non-gated power supply (408), and drain and gate terminals coupled to the local power supply (414).

11. The method of claim 8, wherein the retention circuit (204) reduces a leakage current associated with the retention circuit (204) during the low power period.

12. The method of claim 8, further comprising coupling the isolation element (212) to a non-gated power supply net (304) using a signal wire (310).

13. The method of claim 8, wherein the isolation element (212) reduces the leakage current of the retention circuit (204) during a low power period and isolates a noise signal from coupling with the retention circuit (204) from the non-gated power supply (208).

14. The method of claim 8, further comprising coupling a signal wire (310) between a non-gated power supply net (304) and the isolation element (212).

15. An integrated circuit, comprising:
a first power grid (102) coupled to a gated power supply (206) that is shut down during a low power period;
a power gated circuit (202) coupled to the first power grid during at least a portion of a non-low power period;
a retention circuit (204) coupled to the power gated circuit during at least a portion of the non-low power period, wherein the retention circuit stores, during the low power period, state information of a state of the power gated circuit before the low power period started;
a second power grid (304) coupled to a non-gated power supply (208) that does not shut down during the low power period; and
a local power supply rail (214) coupled to the first power grid via a power supply switch (210) and coupled to the second power grid via an isolation element (212);
wherein the local power supply rail is coupled to the retention circuit and supplies the gated supply voltage to the retention circuit during the non-low power period, and supplies the non-gated power supply to the retention circuit during the low power period;
wherein the isolation element isolates the non-gated power supply from the local power supply rail during the non-low power period.

16. The integrated circuit of claim 15, wherein the first power grid (102) comprises a power mesh plane (302) and the second power grid (304) comprises a signal wire ring (310);
wherein the signal wire ring comprises metal wire lines normally used to route non-power supply signals and substantially narrower than a width of the power mesh lines of the first power grid;
wherein the integrated circuit comprises multiple metal layers and the signal wire ring uses a topmost one of the metal layers.

17. The integrated circuit of claim 16, wherein the first power grid is coupled to a plurality of de-coupling capacitors distributed along with the power mesh plane to decouple high frequency switching noise or IR drop during at least the portion of the non-low power period of operation, and wherein the second power grid does not have de-coupling capacitors distributed along the signal wire ring.

18. The integrated circuit of claim 15, wherein the power supply switch comprises:
a PMOS pass-gate transistor (410) having a source terminal coupled to the local power supply rail, a drain terminal coupled to the first power grid and a gate terminal; and
a supply switch inverter (418) having an output terminal coupled to the gate terminal of the PMOS pass-gate transistor, and an input terminal coupled to a low power mode control signal (pgb),
wherein during the non-low power period the local power supply rail is coupled to the gated power supply via the PMOS pass-gate transistor.

19. The integrated circuit of claim 18, wherein the supply switch inverter has a first supply rail coupled to the non-gated power supply via the second power grid and a second supply rail coupled to ground VSS, and wherein the supply switch inverter further comprises one or more NMOS transistors (416) that reduce leakage current during the low power period.

20. The integrated circuit of claim 19, wherein at least one of the power supply switch and the isolation element comprise part of a state retention power gating (SRPG) cell.
